(19) United States
(12) Patent Application Publication
(10) Pub. No.: US 2008/0316694 A1
(43) Pub. Date: Dec. 25, 2008

(54) LATCHING MECHANISM AND BASE CASING OF NOTEBOOK COMPUTER USING THE SAME

(75) Inventors: Sheng-Te Yang, Taipei City (TW); Chun-Ching Hsu, Taipei City (TW); Kuo-Chun Ling, Taipei City (TW); Chia-Wei Fu, Taipei City (TW); Jen-Chieh Tsai, Taipei City (TW); Yen-Chieh Chiu, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: COMPAL ELECTRONICS, INC., Taipei City (TW)

(21) Appl. No.: 12/035,440

(22) Filed: Feb. 22, 2008

(30) Foreign Application Priority Data
Jun. 21, 2007 (TW) 96122288

(51) Int. Cl. H05K 7/14

(52) U.S. Cl. 361/683; 16/232

(57) ABSTRACT

A latching mechanism for being mounted between a housing and a cover of an electronic device includes a sliding member, a first latching portion, a second latching portion and an elastic member. The sliding member is slidably disposed on the cover and has a pushed portion located at a side of the cover. The first latching portion is fixed to the sliding element. The second latching portion is fixed to the housing and adapted for engaging with the first latching portion. The elastic member is disposed between the sliding member and the cover for providing an elastic force to the sliding member against the cover.

### CROSS-REFERENCE TO RELATED APPLICATION

This application claims the priority benefit of Taiwan application serial no. 96122288, filed on Jun. 21, 2007. The entirety of the above-mentioned patent application is hereby incorporated by reference herein and made a part of this specification.

### BACKGROUND OF THE INVENTION

1. Field of the Invention

The present invention relates to a latching mechanism, and more particularly, to a latching mechanism disposed on a base casing of a notebook computer.

2. Description of Related Art

Notebook computers usually include a base and a display pivotably attached to the base. When electronic components within the base need to be repaired, a cover of a housing of the base casing must be removed to expose the electronic components beneath the cover for repair. The cover and the housing conventionally include a plurality of hooks and openings, respectively, and the cover is assembled to the housing by engaging the hooks in the openings.

The above latch assembling method can rapidly assemble the cover to the housing. However, the location of the hooks is uneasy to find, and, therefore, the maintenance engineer may spend a lot of time searching for the location of the hooks so as to disengage the hooks from corresponding openings. As a result, it can be laborious to repair the notebook computer and hence increasing the time for repair.

### SUMMARY OF THE INVENTION

The present invention is directed to a latching mechanism for being mounted between a housing and a cover of an electronic device for assembling the cover to the housing.

The present invention is also directed to a base casing of a notebook computer that includes a latching mechanism for assembling a cover to a housing of the notebook computer.

The present invention provides a latching mechanism for being mounted between a housing and a cover of an electronic device. The latching mechanism includes a sliding member, a first latching portion, a second latching portion and an elastic member. The sliding member is slidably disposed on the cover and includes a pushed portion located on a side of the cover. The first latching portion is fixed to the sliding member. The second latching portion is fixed to the housing and adapted for engaging with the first latching portion. The elastic member is disposed between the sliding member and the cover and adapted for providing an elastic force to the sliding member against the cover.

In one embodiment of the present invention, the latching mechanism further includes a position limiter disposed on the cover. The position limiter is adapted for limiting a sliding range of the sliding member.

In one embodiment of the present invention, one of the first latching portion and the second latching portion is a hook, and the other of the first latching portion and the second latching portion is an opening.

In one embodiment of the present invention, the pushed portion comprises a notch open towards an exterior of the cover.

In one embodiment of the present invention, the notch is a V-shaped straight notch

In one embodiment of the present invention, the elastic member comprises a helical spring attached around a shaft formed on one end of the sliding member.

In one embodiment of the present invention, the latching mechanism is a sheet shaped latching mechanism.

The present invention also provides a base casing of a notebook computer. The base casing includes a housing, a cover and a latching mechanism. The latching mechanism is mounted between the housing and the cover to assemble the cover to the housing. The latching mechanism includes a sliding member, a first latching portion, a second latching portion and an elastic member. The sliding member is slidably disposed on the cover and includes a pushed portion located on a side of the cover. The first latching portion is fixed to the sliding member. The second latching portion is fixed to the housing and adapted for engaging with the first latching portion. The elastic member is disposed between the sliding member and the cover and adapted for providing an elastic force to the sliding member against the cover.

In one embodiment of the present invention, the latching mechanism further includes a position limiter disposed on the cover. The position limiter is adapted for limiting a sliding range of the sliding member.

In one embodiment of the present invention, one of the first latching portion and the second latching portion is a hook, and the other of the first latching portion and the second latching portion is an opening.

In one embodiment of the present invention, the pushed portion comprises a notch open towards an exterior of the cover.

In one embodiment of the present invention, the notch is a V-shaped straight notch.

In one embodiment of the present invention, the elastic member comprises a helical spring attached around a shaft formed on one end of the sliding member.

In one embodiment of the present invention, the base casing of the notebook computer further includes a receiving slot located on a surface of the cover and adapted for receiving a locking member.

In one embodiment of the present invention, the housing further comprises a battery compartment.

In one embodiment of the present invention, the battery compartment is located in an area of the housing that is projected with the cover in a direction perpendicular to a surface of the cover.

In one embodiment of the present invention, the cover is secured to the housing by the locking member inserting through a bottom wall of the battery compartment and locked to the cover.

In one embodiment of the present invention, the locking member includes a screw.

In one embodiment of the present invention, the latching mechanism is a sheet shaped latching mechanism.

In the present invention, the sliding member is slidably disposed on the cover, and sliding of the sliding member can move the first latching portion relative to the second latching portion, which enables the first latching portion to disengage from the second latching portion, thereby achieving rapid disassembling of the cover from the housing.

In order to make the aforementioned and other features and advantages of the present invention more comprehensible, embodiments accompanied with figures are described in detail below.

### BRIEF DESCRIPTION OF THE DRAWINGS

FIG. 1A is a perspective view of one embodiment of a base casing of a notebook computer.

FIG. 1B is a perspective view of the base casing of the notebook computer of FIG. 1A, viewed from another direction.

FIG. 1C is a perspective view of a cover and a latching mechanism of FIG. 1B.

FIGS. 2A through 2C are enlarged partial views of FIGS. 1A through 1C, respectively.

FIGS. 3 is a top view of FIG. 2C.

FIG. 4A is a cross sectional view of FIG. 3 taken along line I-I thereof.

FIG. 4B is a cross sectional view illustrating the sliding member of FIG. 4A moved relative to the cover.

### DESCRIPTION OF THE EMBODIMENTS

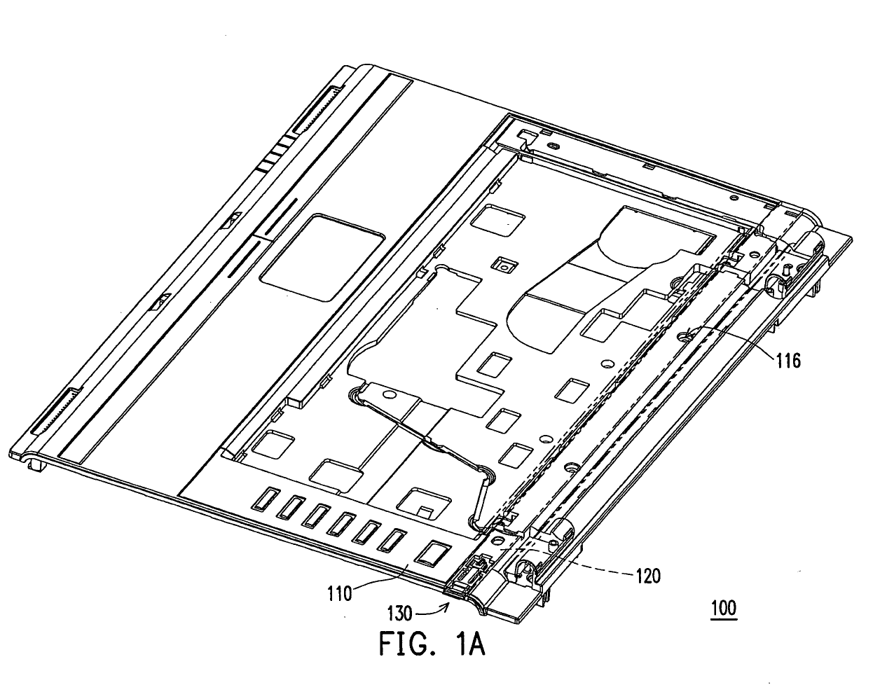

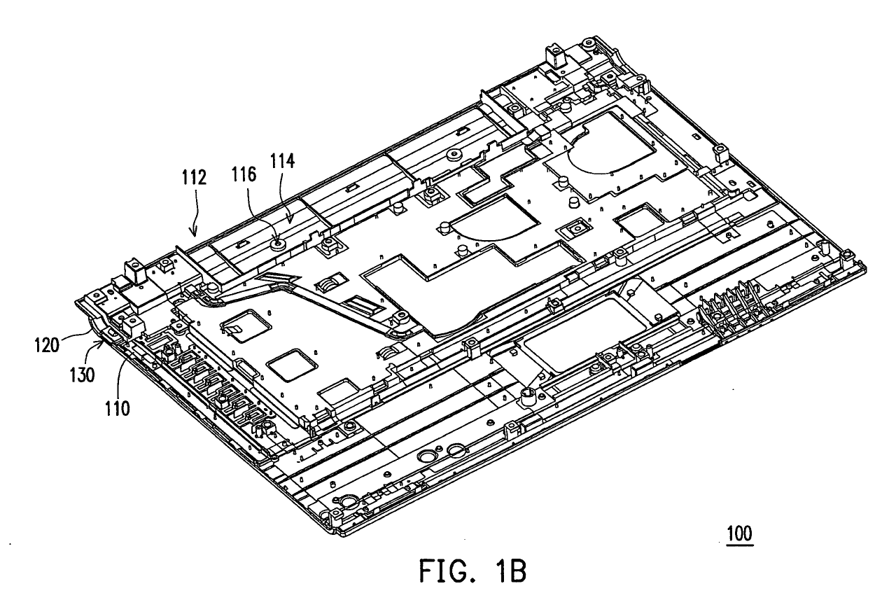

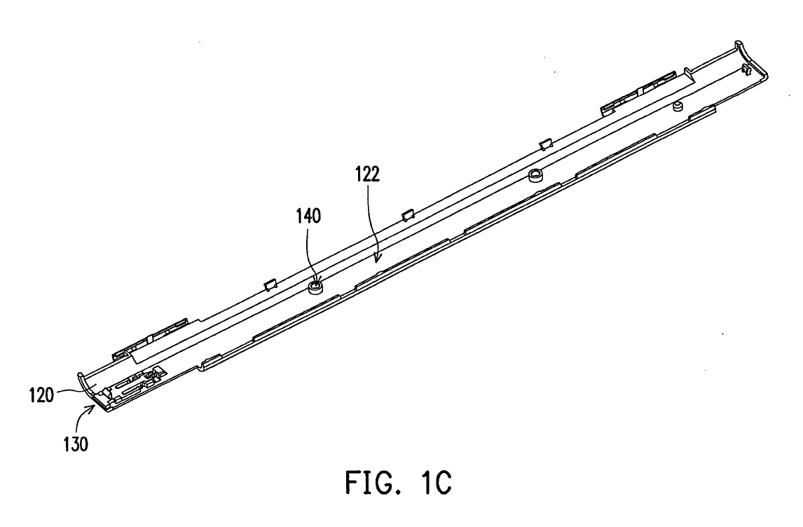

FIG. 1A is a perspective view of one embodiment of a base casing of a notebook computer, FIG. 1B is a perspective view of the base casing of the notebook computer of FIG. 1A, viewed from another direction, and FIG. 1C is a perspective view of a cover and a latching mechanism of FIG. 1B. Referring to FIGS. 1A through 1C, the base casing 100 of the notebook computer includes a housing 110, a cover 120, and a latching mechanism 130. The latching mechanism 130 is mounted between the housing 110 and the cover 120 to assemble the cover 120 to the housing 110.

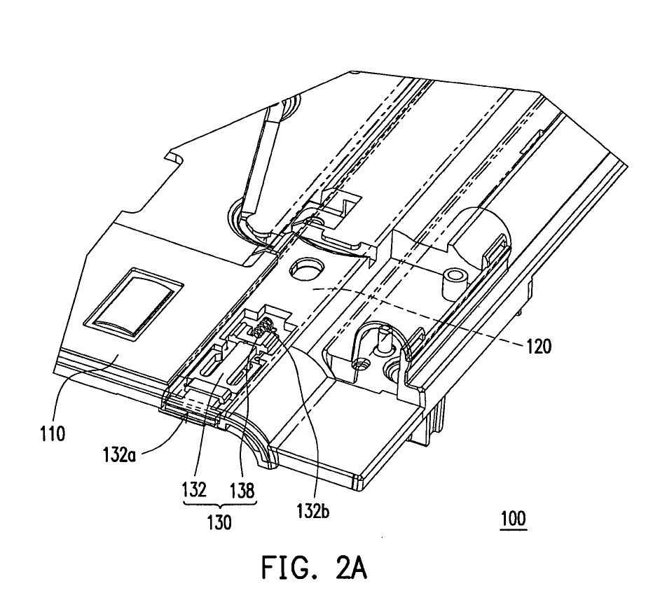

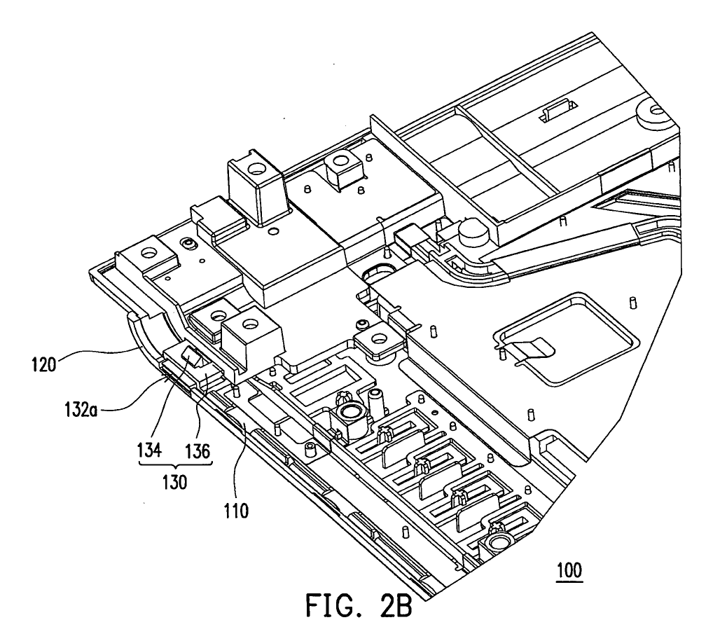

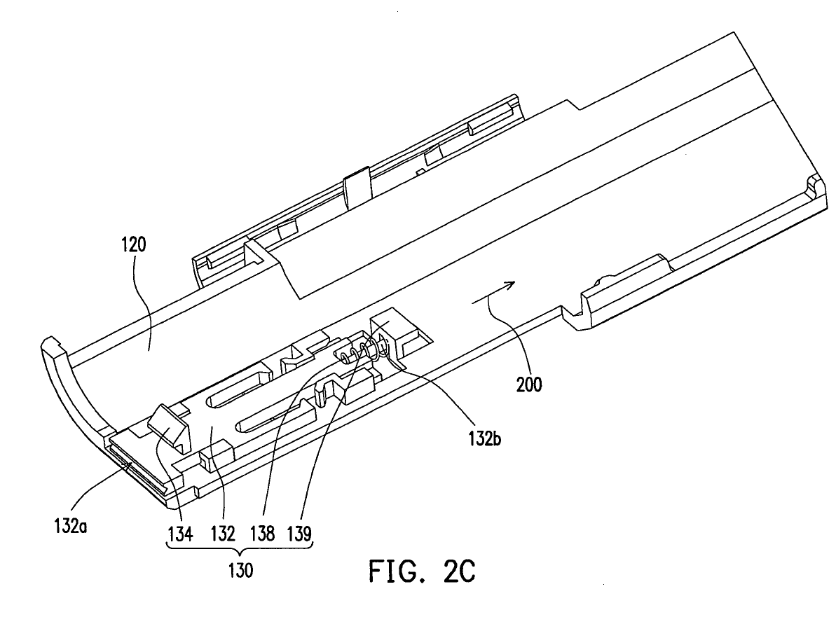

FIGS. 2A through 2C are enlarged partial views of FIGS. 1A through 1C, respectively. Referring to FIGS. 2A through 2C, in the illustrated embodiment, the latching mechanism 130 is, for example, a sheet shaped latching mechanism, and includes a sliding member 132, a first latching portion 134, a second latching portion 136, and an elastic member 138. The sliding member 132 is slidably disposed on the cover 120, and includes a pushed portion 132a exposed from one side of the cover 120. The first latching portion 134 is, for example, a hook fixed on the sliding member 132. The second latching portion 136 is, for example, fixed to the housing 110, and includes an opening adapted for engagingly receiving the first latching portion 134. In addition, the sliding member 132 may include a shaft 132b on one end of the sliding member 132 opposite to the pushed portion 132a. The elastic member 138 is disposed between the sliding member 132 and the cover 120. The elastic member 138 is, for example, a helical spring attached around the shaft 132b.

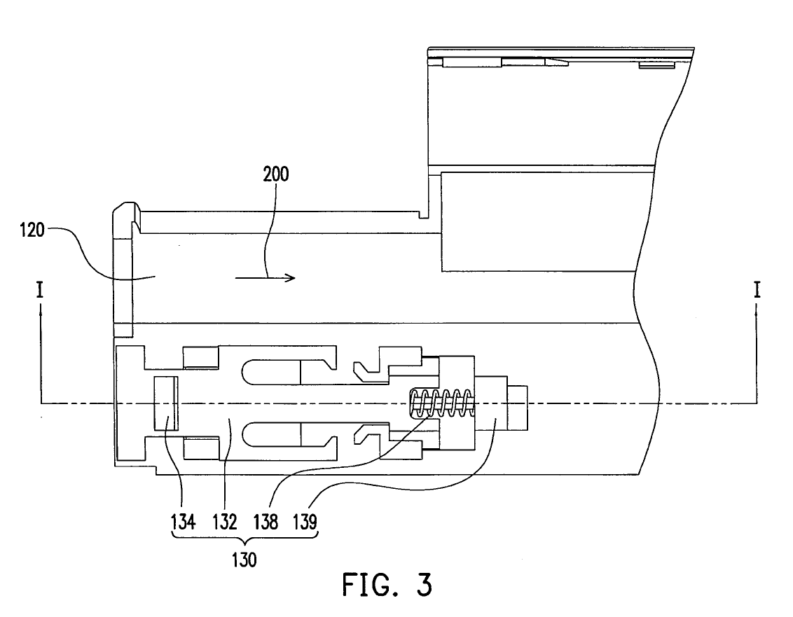

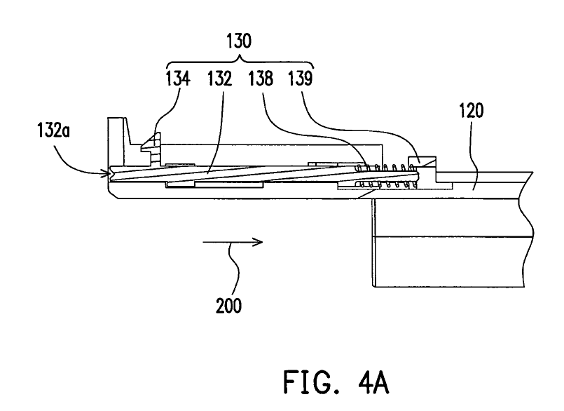

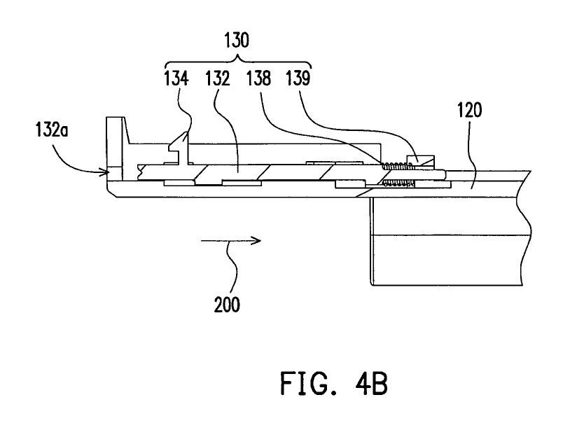

FIGS. 3 is a top view of FIG. 2C, FIG. 4A is a cross sectional view of FIG. 3 taken along line I-I thereof, FIG. 4B is a cross sectional view illustrating the sliding member of FIG. 4A moved relative to the cover. Referring to FIGS. 3, 4A and 4B, when the pushed portion 132a is pushed by an external force, for example, being pushed by fingers directly or tools such as a screwdriver, the sliding member 132 is moved relative to the cover 120 from the position illustrated in FIG. 4A to the position illustrated in FIG. 4B along a first direction 200. In this position, the elastic member 138 (helical spring) is elastically deformed due to the compression of the sliding member 132 and the cover 120, and the first latching portion 134 (hook) can escape through the second latching portion 136 (opening). In other words, the first latching portion 134 and the second latching portion 136 are disengaged.

Thereafter, when the pushed portion 132a is no longer pushed, the elastic member 138 (helical spring) will provide a resilient force to the sliding member 132 against the cover 120 to restore the sliding member 132 from the position illustrated in FIG. 4B back to the position illustrated in FIG. 4A. In this position, the cover 120 can be assembled to the housing 110 by engagement of the first latching portion 134 (hook) with the second latching portion 136 (opening) as shown in FIG. 2B.

As described above, to assemble or remove the cover 120 to or from the housing 110, a user needs only to push the pushed portion 132a to disengage the first latching portion 134 and the second latching portion 136. Therefore, the present invention is capable of achieving easy and rapid disassembling of the cover and the housing, which not only can reduce the time in disassembling the cover 120, but also can avoid the damage to the cover 120 due to improper force exerted thereon in disassembling the cover 120.

In the illustrated embodiment, the pushed portion 132a does not extend beyond the side of the cover 120, and may include a V-shaped straight notch open to an exterior of the cover 120. This notch may prevent the sliding member 132 from being accidentally moved relative to the cover 120, so as to prevent the cover 120 from being disengaged from the housing 110 accidentally. In this case, the user must utilize a screwdriver or other tools having flat projection to push the pushed portion 132a to slide the sliding member 132 relative to the cover 120. In addition, the latching mechanism 130 may further include a position limiter 139 disposed on the cover 120. The position limiter 139 may be used to limit a slide range of the sliding member 132 sliding relative to the cover 120. It is to be noted that the notch in the pushed portion 132a is not limited to V-shaped, for example, it may be of U-shaped or other suitable shapes.

Furthermore, referring again to FIGS. 1A through 1C, the base casing 100 of the notebook computer may further include a receiving slot 140 (as shown in FIG. 1C) located on a surface 122 of the cover 120. The receiving slot 140 is, for example, a screw hole. Moreover, the housing 110 may further include a battery compartment 112 (as shown in FIG. 1B) and a through hole 116 defined at a bottom wall 114 of the battery compartment 112. The battery compartment 112 is adapted for receiving a battery (not shown) therein, and is positioned in an area of the housing 110 that is projected with the cover 120 in a direction perpendicular to a surface of the cover 120.

In other words, the battery compartment 112 and the cover 120 are disposed at opposite two sides of the housing 110, and the battery compartment 112 is disposed at an opposite side of an area of the housing 110 covered by the cover 120 when the cover 120 is assembled to the housing 110. Therefore, when the cover 120 is assembled to the housing 110, the user may secure the cover 120 to the housing 110 by inserting a locking member (not shown), for example, a screw, through the through hole 116 of the bottom wall 114 of the battery compartment 112 and engaging the locking member in the receiving slot 140.

In this case, to disengage the cover 120 from the housing 110, the user must first remove the battery to expose the locking member and then remove the locking member from the receiving slot 140 and the through hole 116. Therefore, with the above design, the situation where the cover 120 is removed from the housing 110 before the battery is removed can be prevented, and in turn the damage to the notebook computer caused by the non-removal of the battery in repairing the notebook computer is avoided.

In summary, in the present invention, the sliding member is slidably disposed on the cover, and sliding of the sliding member can move the first latching portion relative to the second latching portion, which enables the first latching portion to disengage from the second latching portion, thereby achieving rapid disassembling of the cover from the housing. Furthermore, the cover may be secured to the housing by using a locking member first inserted through the housing and then locked to a receiving slot of the cover. As a result, to disassemble the cover from the housing, the user must first remove the locking member disposed on the bottom wall of the battery compartment.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A latching mechanism, for being mounted between a housing and a cover of an electronic device, comprising:
a sliding member slidably disposed on the cover and comprising a pushed portion located on a side of the cover;
a first latching portion fixed to the sliding member;
a second latching portion fixed to the housing, and adapted for engaging with the first latching portion; and
an elastic member disposed between the sliding member and the cover, the elastic member adapted for providing an elastic force to the sliding member against the cover.

2. The latching mechanism in accordance with claim 1, further comprising a position limiter disposed on the cover, adapted for limiting a sliding range of the sliding member.

3. The latching mechanism in accordance with claim 1, wherein one of the first latching portion and the second latching portion comprises a hook, and the other of the first latching portion and the second latching portion comprises an opening.

4. The latching mechanism in accordance with claim 1, wherein the pushed portion comprises a notch open towards an exterior of the cover.

5. The latching mechanism in accordance with claim 4, wherein the notch is a V-shaped straight notch.

6. The latching mechanism in accordance with claim 1, wherein the elastic member comprises a helical spring attached around a shaft formed on one end of the sliding member.

7. The latching mechanism in accordance with claim 1, wherein the latching mechanism is a sheet shaped latching mechanism.

8. A base casing of a notebook computer, comprising:
a housing;
a cover; and
a latching mechanism mounted between the housing and the cover to assemble the cover to the housing, the latching mechanism comprising:
a sliding member slidably disposed on the cover and comprising a pushed portion located on a side of the cover;
a first latching portion fixed to the sliding member;
a second latching portion fixed to the housing, and adapted for engaging with the first latching portion; and
an elastic member disposed between the sliding member and the cover, the elastic member adapted for providing an elastic force to the sliding member against the cover.

9. The base casing of a notebook computer in accordance with claim 8, further comprising a position limiter disposed on the cover, adapted for limiting a sliding range of the sliding member.

10. The base casing of a notebook computer in accordance with claim 8, wherein one of the first latching portion and the second latching portion comprises a hook, and the other of the first latching portion and the second latching portion comprises an opening.

11. The base casing of a notebook computer in accordance with claim 8, wherein the pushed portion comprises a notch open towards an exterior of the cover.

12. The base casing of a notebook computer in accordance with claim 11, wherein the notch is a V-shaped straight notch.

13. The base casing of a notebook computer in accordance with claim 8, wherein the elastic member comprises a helical spring attached around a shaft formed on one end of the sliding member.

14. The base casing of a notebook computer in accordance with claim 8, further comprising a receiving slot located on a surface of the cover and adapted for receiving a locking member.

15. The base casing of a notebook computer in accordance with claim 14, wherein the housing further comprises a battery compartment.

16. The base casing of a notebook computer in accordance with claim 15, wherein the battery compartment is located in an area of the housing that is projected with the cover in a direction perpendicular to a surface of the cover.

17. The base casing of a notebook computer in accordance with claim 15, wherein the cover is secured to the housing by the locking member inserting through a bottom wall of the battery compartment and locked to the cover.

18. The base casing of a notebook computer in accordance with claim 14, wherein the locking member comprises a screw.

19. The base casing of a notebook computer in accordance with claim 8, wherein the latching mechanism is a sheet shaped latching mechanism.
